(19) United States
(12) Patent Application Publication
(10) Pub. No.: US 2022/0165626 A1
(43) Pub. Date: May 26, 2022

(54) FEED-FORWARD RUN-TO-RUN WAFER PRODUCTION CONTROL SYSTEM BASED ON REAL-TIME VIRTUAL METROLOGY

(71) Applicant: Yangtze Memory Technologies Co., Ltd., Wuhan (CN)

(72) Inventors: Fatih OLMEZ, Wuhan (CN); Liang DONG, Wuhan (CN); Fan WANG, Wuhan (CN); Yunlong WANG, Wuhan (CN); Zhenyu YANG, Wuhan (CN); Tianyu ZHANG, Wuhan (CN); Yan LI, Wuhan (CN)

(73) Assignee: Yangtze Memory Technologies Co., Ltd., Wuhan (CN)

(21) Appl. No.: 17/190,655

(22) Filed: Mar. 3, 2021

Related U.S. Application Data
(63) Continuation of application No. PCT/CN2020/130422, filed on Nov. 20, 2020.

(51) Int. Cl. H01L 21/66; G01R 31/28

(52) U.S. Cl. CPC H01L 22/10; G01R 31/2894; H01L 22/26

(57) ABSTRACT

Aspects of the disclosure provide an APC system. The APC system can include a first processing tool that performs a first process on a target wafer, a second processing tool that performs a second process on the target wafer, and a prediction server that includes a prediction model for predicting a characteristic of the target wafer resulting from the first process using real-time data from the first process performed on the target wafer. Parameters of the prediction model can be updated by historical data of previous first processes. The APC system can also include a controller that is coupled to the first and second processing tools. After the first processing tool performs the first process on the target wafer, the controller can instruct the second processing tool to perform an adjusted second process on the target wafer based on the characteristic of the target wafer predicted by the prediction model.

### RELATED APPLICATION

This application is a bypass continuation of International Application No. PCT/CN2020/130422, filed on Nov. 20, 2020. The entire disclosure of the prior application is hereby incorporated by reference in its entirety.

### TECHNICAL FIELD

The present application relates generally to advanced process control (APC) for semiconductor fabrication and, more particularly to, virtual metrology (VM).

### BACKGROUND

As semiconductor devices continue to shrink and become more three-dimensional (3D), APC has become an essential component in semiconductor manufacturing for improving device yield and reliability at a reduced cost. Run-to-run (R2R) control, a form of APC, is defined as a form of discrete process and machine control in which the product recipe with respect to a particular machine process is modified ex situ, i.e., between machine “runs,” so as to minimize process drift, shift, and variability. Most R2R technologies found in the market today can make automatic process tunings to reach a target CD or thickness. This is achieved through automated use of metrology data and implementing custom schemes. When a process run is a batch or a lot rather than a workpiece, large amounts of metrology data are required. Therefore, production cycle time will be increased significantly, not to mention potential metrology delays.

To alleviate the problems, VM has been developed. VM utilizes an empirical prediction model that is developed by using information about the state of the process of historical workpieces. The empirical prediction model is refined until the predicted values from the VM model correlates to actual metrology data. If the VM model is updated in a timely fashion to keep it accurate within a reasonable range, it can be used to generate a predicted VM value within seconds after collecting manufacturing data of a workpiece from a corresponding processing tool. Hence, a VM model can significantly simplify semiconductor fabrication and reduce production cycle time.

### SUMMARY

Aspects of the disclosure provide advanced process control (APC) systems and a method of implementing an APC system.

According to a first aspect, an APC system is provided. The APC system can include a first processing tool that performs a first process on a target wafer and a second processing tool that performs a second process on the target wafer after the first process has been completed. The APC system can also include a prediction server that includes a prediction model for predicting a characteristic of the target wafer resulting from the first process using real-time data from the first process performed on the target wafer. Parameters of the prediction model can be updated by historical data of previous first processes. The APC system can further include a controller that is coupled to the first and second processing tools, wherein after the first processing tool performs the first process on the target wafer, the controller instructs the second processing tool to perform an adjusted second process on the target wafer based on the characteristic of the target wafer predicted by the prediction model.

In some embodiments, the APC system can include a model training server for updating a training model using the historical data so that parameters of the training model are synced to the prediction model. Further, the historical data can be updated by adding the real-time data to the historical data at a frequency, and the trained model can be updated based on the updated historical data so that the prediction model is updated at the frequency. For example, the frequency can be about once every five minutes or higher.

In some embodiments, the APC system can include a buffer that queues requests from the prediction server and employs an available controller.

In some embodiments, the historical data can include manufacturing data of the previous first processes collected by the first processing tool, and the real-time data can include manufacturing data from performing the first process on the target wafer collected by the first processing tool. Further, the historical data can include metrology data of the previous first processes.

In some embodiments, the predicted characteristic of the target wafer resulting from the first process can include at least one of critical dimension (CD) or etch rate (ER). In one embodiment, the first process is an etching process, and the first processing tool is an etching tool. Further, the historical data can include at least one of CD or ER of the previous first processes and at least one of temperature, etchant, pressure, flow rate, or process time of the previous first processes, and the real-time data can include at least one of temperature, etchant, pressure, flow rate, or process time of the first process performed on the target wafer. In another embodiment, the second process is an etching process, and the second tool is an etching tool. Further, at least one of temperature, etchant, pressure, flow rate, or process time can be adjusted by the controller to perform the adjusted second process.

According to a second aspect of the disclosure, an APC system is provided. The APC system can include a first processing tool that performs a first process on a target wafer and a second processing tool that performs a second process on the target wafer after the first process has been completed. The APC system can also include a controller that is coupled to the first and second processing tools, wherein after the first processing tool performs the first process on the target wafer, the controller instructs the second processing tool to perform an adjusted second process on the target wafer based a characteristic of the target wafer resulting from the first process, the characteristic of the target wafer being predicted by a prediction model using real-time data from the first process performed on the target wafer, parameters of the prediction model being updated by historical data of previous first processes.

According to a third aspect of the disclosure, a method for implementing an APC system is provided. The method can include performing a first process on a target wafer using a first processing tool. A prediction model in a prediction server can be updated based on historical data. A characteristic of the target wafer resulting from the first process can be predicted based on real-time data using the prediction model. An adjusted second process can be performed on the target wafer using a second processing tool that is instructed by a controller that receives the predicted characteristic of the target wafer from the prediction server and adjusts process inputs for the second processing tool.

In some embodiments, updating the prediction model in the prediction server based on the historical data includes updating a training model in a model training server using the historical data, and syncing parameters of the training model to the prediction model. Further, the historical data can be updated by adding the real-time data to the historical data at a frequency, and the trained model can be updated based on the updated historical data so that the prediction model is updated at the frequency. For example, the frequency can be about once every five minutes or higher.

In some embodiments, after predicting the characteristic of the target wafer resulting from the first process based on the real-time data using the prediction model, the predicted characteristic of the target wafer can be transferred from the prediction server to a buffer that queues requests from the prediction server and employs an available controller.

In some embodiments, a plurality of historical wafers can be processed using the first processing tool, and the historical data can be collected on the plurality of historical wafers. Further, collecting the historical data on the plurality of historical wafers can include collecting manufacturing data on the historical wafers from the first processing tool, and collecting metrology data on the historical wafers from a metrology tool.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be increased or reduced for clarity of discussion.

FIG. 1 is a block diagram of a first APC system, in accordance with exemplary embodiments of the disclosure.

FIG. 2 is a block diagram of a second APC system, in accordance with exemplary embodiments of the disclosure.

FIGS. 3A, 3B, and 3C show cross-sectional views of a semiconductor device at various machine runs controlled by an APC system, in accordance with exemplary embodiments of the disclosure.

FIG. 4 shows a flowchart of an exemplary method for implementing an APC system, in accordance with exemplary embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features may be in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As described above, VM has been utilized to improve R2R technologies. An issue with the current R2R technologies lies in the fact that they were developed during the industry 3.0 era when automating everything was the driving force of the market. In the industry 4.0 era, processes are almost completely automated and manufacturing data are recorded at every step that one can imagine. A bottleneck now is to solve how to integrate big data based intelligent solutions into the existing R2R solutions from the previous era. Particularly, implementing VM solutions into a R2R controller at a semiconductor fab is of great significance.

There are two main issues that are most visible when implementing a VM solution to a R2R system. First, machine learning and neural network solutions are dependent on very large data availability. Semiconductor fabrication plants produce high volume data every second, and this must be transferred to prediction models at a fast speed to make use of the latest data. Equipment and chamber natures gradually change over time. Prediction model training must be frequent to capture the latest status of the equipment and chamber. Second, when a wafer is moving from tool n to n+1, reducing the wait time in-between is crucial. When introducing a VM solution in between, the time spent on obtaining all the relevant data from tool n to make the VM prediction to be used at tool n+1 must be as short as possible. Current R2R technologies are not built to handle high frequency training data-heavy models and real-time predictions.

Techniques herein encapsulate model training and prediction jobs in isolated environments, and the model training environment periodically one-way syncs to the prediction server. This can enable high frequency model training by making use of the most recent data available at the fab and allow the model to “learn” the latest equipment/chamber nature. Moreover, model prediction server responds to standard queries from the main R2R that first go through a buffer (also referred to as a broker) if there are multiple prediction and R2R servers, which can enable fast feed forward metrology predictions to high volume manufacturing in a reliable manner.

Aspects of the present disclosure provide APC systems built on top of the big data platform of the fab. The model training and predictions can be performed on two separate servers. A model can be trained about every five minutes (or more frequently) on historical data (e.g., thousands of wafers spanning a period of 10-30 days, corresponding to about 10-100 GB data). Every trained model can consist of a set of model parameters which are synced to the prediction server (maybe multiple prediction servers in some cases). Predictions require real-time data of wafers that are finished being processed in the equipment. In normal times, predictions are needed at least a few times per minute. High volume manufacturing may increase this need to a few times per second.

This architecture can also be easily expanded to make predictions for multiple products and multiple R2R controllers. In the case of multiple R2R controllers and training and prediction servers, a buffer between the R2R controller and model servers can be used to queue requests from the R2R system and employs an available prediction server to fulfill the request.

In an exemplary embodiment of the disclosure, an APC system can include a first processing tool, a second processing tool, a prediction server, and a controller. The prediction server can include a prediction model that predicts a wafer characteristic using real-time data, and parameters of the prediction model can be updated by historical data. In another embodiment where a plurality of prediction servers and controllers are involved, the APC system can further include a buffer that queues requests from the prediction servers and employs an available controller.

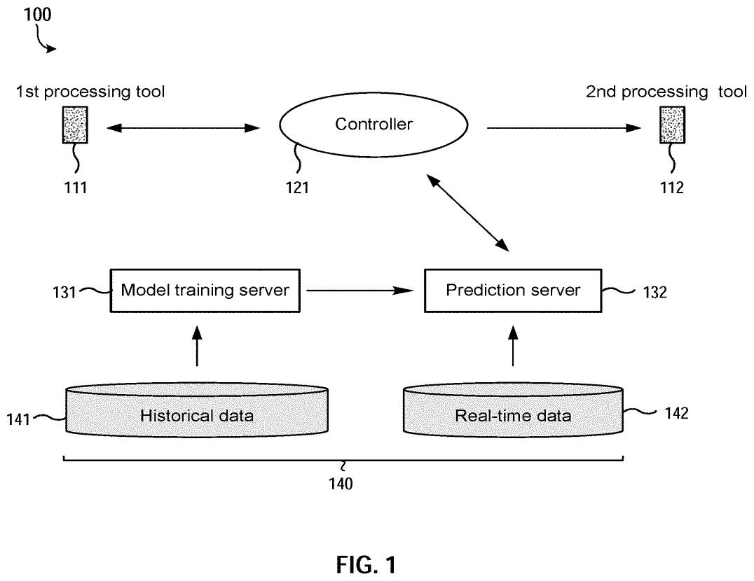

FIG. 1 is a block diagram of a first APC system 100, in accordance with exemplary embodiments of the disclosure. As shown, the APC system 100 can include a first processing tool 111 and a second processing tool 112, with a controller 121 coupled to each. During operation, the first processing tool 111 performs a first process on a target wafer, and the second processing tool 112 performs a second process on the target wafer after the first process has been completed. After the first processing tool 111 performs the first process on the target wafer, the controller 121 can receive a prediction from a model (VM model) that predicts a wafer characteristic of interest resulting from the first process. Based on the prediction, the controller 121 can adjust process inputs for the second processing tool 112, and thus instruct the second processing tool 112 to perform an adjusted second process on the target wafer. By adjusting the process inputs for the second processing tool 112, the wafer characteristic of interest can be controlled to fall within a desirable range after the second process. In some embodiments, the controller 121 can also instruct the first processing tool 111 for performing the first process on the target wafer. Further, the controller 121 may receive the real-time data 142 from the first processing tool 111 and send the real-time data 142 to the prediction server 132.

The first or second process can include any semiconductor process, such as plasma etching, epitaxy, thermal oxidation, ion implantation, chemical vapor deposition, rapid thermal annealing, chemical mechanical polishing, wet cleaning, and the like. Accordingly, the first processing tool 111 and the second processing tool 112 can include any corresponding semiconductor tool in the fabrication process. The first process can include a first step or any intermediate step of a set of semiconductor processes, such as front-end-of-line processing, back-end-of-line processing, lithographic patterning, integrated circuit packaging, and the like. In some embodiments, the first process can include a different process from the second process, so that the first processing tool 111 includes a different tool from the second processing tool 112. In other embodiments, the first process can include a same process from the second process. As a result, the first processing tool 111 may include a same tool as the second processing tool 112. Additionally, the first processing tool 111 and the second processing tool 112 can also, respectively, perform the first and second processes on a target batch or a target lot rather than a target workpiece (i.e., the target wafer).

As illustrated in FIG. 1, the APC system 100 can further include a prediction server 132 that is coupled to the controller 121. The prediction server 132 can include a prediction model for predicting a characteristic of the target wafer resulting from the first process using real-time data 142 from performing the first process on the target wafer. During operation, parameters of the prediction model can be updated by historical data 141 of previous first processes. Hence, the controller 121 can instruct the second processing tool 112 to perform the adjusted second process on the target wafer based on the characteristic of the target wafer predicted by the prediction model in the prediction server 132. Further, the real-time data 142 and the historical data 141 can form a data platform 140.

In some embodiments, the APC system 100 can further include a model training server 131 that includes a training model. The model training server 131 can update the training model using the historical data 141 so that parameters of the training model are synced to the prediction model.

In some embodiments, the historical data 141 can be collected from historical wafers processed by the first processing tool 111. For example, the historical wafers can include a plurality of wafers spanning a period of the past ten to thirty days. In some embodiments, the historical data 141 can be updated by adding the real-time data 142 to the historical data 141 at a first frequency, and the trained model can be updated based on the updated historical data 141 so that the prediction model is updated at the first frequency. The prediction model can be used to predict the wafer result(s) at a second frequency. The second frequency can be higher than the first frequency. For example, the first frequency can be about once every five minutes or even more frequent, and the second frequency can range from a few times per minute to a few times per second. As a result, by separating the prediction model from the training model and syncing the updated training model to the prediction model frequently, the prediction model can effectively function as a real-time model by making use of the most recent data and learning the latest tool nature/status.

Still referring to FIG. 1, it should be noted that the historical data 141 can include manufacturing data of the previous first processes collected by the first processing tool 111, and the real-time data 142 can include manufacturing data from performing the first process on the target wafer collected by the first processing tool 111. In some embodiments, the historical data 141 can further include metrology data of the previous first processes collected by a metrology tool. The metrology data can include any wafer characteristic that is related to or results from the first processing tool 111. For example, the metrology data can include an electrical property (e.g., resistivity, carrier mobility, oxide trap density, contact and other parasitic resistance, etc.), an optical property (e.g., reflectivity, optical constant, absorption and emission spectra, etc.), a chemical property (e.g., dopant concentration, film composition, crystal orientation, grain size, etc.), and/or the like. Accordingly, the metrology tool can include any corresponding test or measurement tool. In an embodiment where the first process includes an etching process, the metrology data can include critical dimension (CD) or etch rate (ER). Therefore, the metrology tool can include a length/depth measurement tool, such as an atomic force microscope, a transmission/scanning electron microscope, an optical microscope, a profilometer, a spectroscopic ellipsometer, and the like.

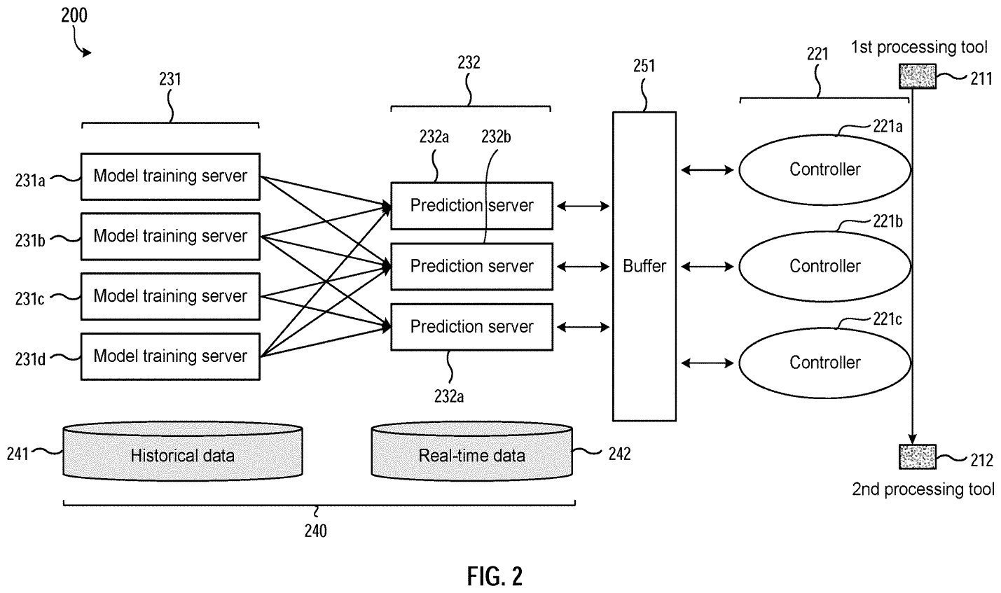

FIG. 2 is a block diagram of a second APC system 200, in accordance with exemplary embodiments of the disclosure. Since the exemplary embodiment of the APC system 200 herein is similar to the exemplary embodiment of the APC system 100 in FIG. 1, explanations will be given with emphasis placed upon differences.

As shown, the APC system 200 can include a first processing tool 211 and a second processing tool 212, with a plurality of controllers 221 (e.g., 221a-221c) in between. The plurality of controllers 221 can be coupled to a plurality of prediction servers 232 (e.g., 232a-232c) via a buffer 251 (also referred to as a broker). The buffer 251 can queue requests from the plurality of prediction servers 232 and employs an available controller 221. The prediction servers 232 can include prediction models for predicting characteristics of target wafers resulting from first processes performed by the first processing tool 211 using real-time data 242 from performing the first processes on the target wafers, and parameters of the prediction models can be updated by historical data 241 of previous first processes. As a result, the controllers 221 can instruct the second processing tools 212 to perform adjusted second processes on the target wafers based on the characteristics of the target wafers predicted by the prediction models in the prediction servers 232. Further, the APC system 200 can include a plurality of model training servers 231 (e.g., 231a-231d) that include and update training models using the historical data 241 so that parameters of the training models are synced to the prediction models.

The first processing tool 211, the second processing tool 212, the historical data 241, and the real-time data 242 can correspond to the first processing tool 111, the second processing tool 112, the historical data 141, and the real-time data 142, respectively. The plurality of controllers 221, the plurality of model training servers 231, and the plurality of prediction servers 232 can correspond to the controller 121, the model training server 131, and the prediction server 132, respectively. Descriptions have been provided above and will be omitted here for simplicity purposes.

In some embodiments, the controllers 221 can instruct the first processing tool 211 for performing the first processes on the target wafers. Further, the buffer 251 may include input and output components and therefore function as an interface between the controllers 221 and the prediction servers 232. In one embodiment, the buffer 251 can receive the real-time data 242 from the controllers 221 and send the real-time data 242 to the prediction servers 232. In another embodiment, the buffer 251 can receive the characteristics of the target wafers predicted by the prediction models from the prediction servers 232 and send the characteristics of the target wafers predicted by the prediction models to the controllers 221.

In some embodiments, one or more of the model training servers 231 are replicas of each other. In some embodiments, one or more of the prediction servers 232 are replicas of each other. In some embodiments, one or more of the controllers 221 are replicas of each other.

In some embodiments, one or more of the model training servers 231 and one or more of the prediction servers 232 can form a group. As a result, the model training servers 231 within the group only sync to the prediction servers 232 within the group, and parameters of the prediction servers 232 within the group are only updated by the model training servers 231 within the group. The group can be used to perform a particular task or process a particular number of wafers. For example, the model training server 231a and the prediction server 232a can be grouped together so that the model training server 231a only syncs to the prediction server 232a and parameters of the prediction server 232a are only updated by the model training server 231a. Further, in high volume manufacturing, a plurality of groups may be formed.

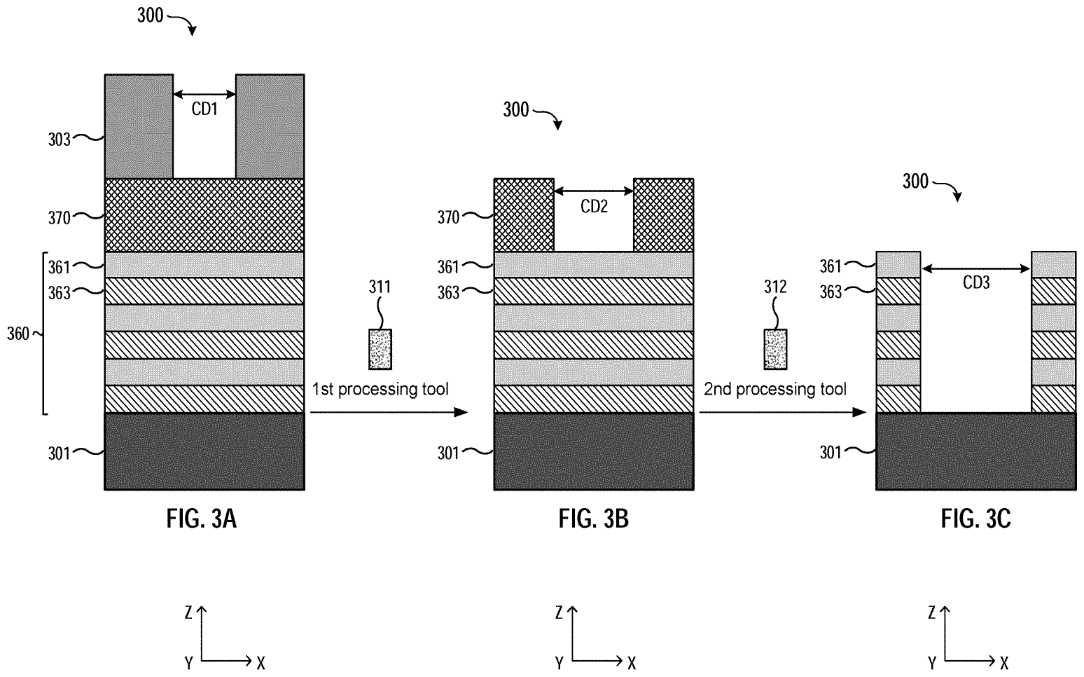

FIGS. 3A-3C show cross-sectional views of a semiconductor device 300 at various machine runs controlled by an APC system, in accordance with exemplary embodiments of the disclosure. Particularly, FIG. 3A can show the semiconductor device 300 before a first process is performed by a first processing tool 311, and FIG. 3B can show the semiconductor device 300 after the first process and before a second process is performed by a second processing tool 312. FIG. 3C can show the semiconductor device 300 after the second process.

In some embodiments, the first processing tool 311 and the second processing tool 312 can correspond to the first processing tool 111 or 211 and the second processing tool 112 or 212, respectively. Further, the APC system herein can correspond to the APC system 100 or the APC system 200. Therefore, while not shown, the APC system herein can also include one or more model training servers, one or more prediction servers, and one or more controllers. In some embodiments, the APC system herein can further include a buffer that corresponds to the buffer 251.

In this example, the first process and the second process are two etching processes so that the first processing tool 311 and the second processing tool 312 can include two etching tools. As shown in FIG. 3A, the semiconductor device 300 can include a substrate 301 and a patterned layer 303 over the substrate 301. The patterned layer 303 can include a photoresist layer or a hard mask layer and have a CD of CD1. A cap layer 370 and an alternating stack 360 can be arranged between the substrate 301 and the patterned layer 303. The alternating stack 360 can alternate between a word line layer (or a sacrificial word line layer) 361 and an insulating layer 363. The semiconductor device 300 can be used to form a vertical NAND device.

In FIG. 3B, a first etching process is performed on the semiconductor device 300 by the first processing tool 311. As a result, the pattern is transferred from the patterned layer 303 to the cap layer 370, and the cap layer 370 can have a CD of CD2. In some embodiments, the first processing tool 311 is a first plasma etching tool. Accordingly, real-time data of the first plasma etching tool can be collected. The real-time data can include at least one of temperature, etchant, pressure, flow rate, or process time of the first etching process performed on the semiconductor device 300. Then, a prediction model can predict CD2 using the real-time data. The predicted CD2 can be larger than, equal to, or smaller than CD1. Subsequently, the controller can instruct the second processing tool 312 to perform an adjusted second process on the semiconductor device 300 based on the predicted CD2.

FIG. 3C can show the semiconductor device 300 after the adjusted second process. As shown, the pattern is further transferred from the cap layer 370 to the alternating stack 360 that can have a CD of CD3. In some embodiments, the second processing tool 312 is a second plasma etching tool. Accordingly, at least one of temperature, etchant, pressure, flow rate, or process time is adjusted by the controller to perform the adjusted second process.

Note that, similar to the APC systems 100 and 200, the prediction model herein can be updated by a training model by using historical data. The historical data can include at least one of temperature, etchant, pressure, flow rate, or process time of the previous first processes. The historical data can also include at least one of CD or ER of the previous first etching processes, measured by a metrology tool. By frequently updating the prediction model, the prediction model can give an accurate estimate of CD2 within a reasonable range and therefore result in a desirable CD3.

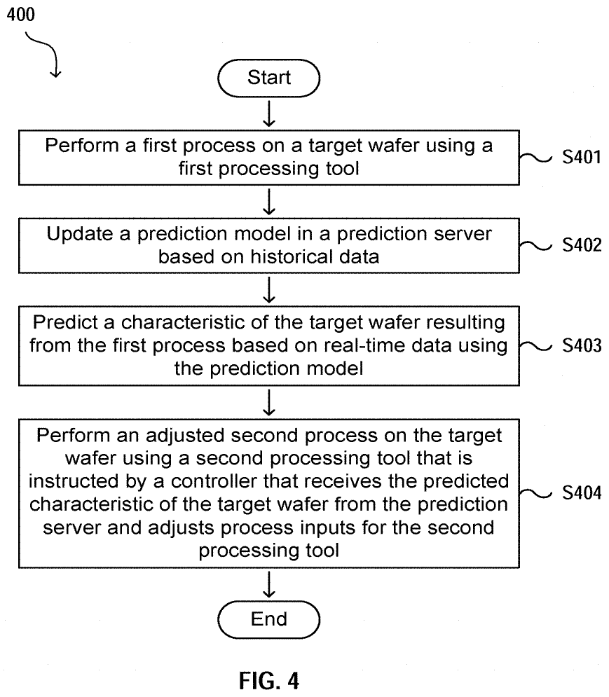

FIG. 4 shows a flowchart of an exemplary method 400 for implementing an APC system, such as the APC systems 100 and 200, in accordance with exemplary embodiments of the disclosure. The process 400 starts with step S401 where a first process is performed on a target wafer using a first processing tool. For example, the first process can be a first etching process, and the first processing tool can be a first etching tool.

At step S402, a prediction model can be updated in a prediction server based on historical data. In some embodiments, a training model in a model training server can be updated using the historical data, and parameters of the training model are synced to the prediction model. In some embodiments, the historical data can be updated by adding the real-time data to the historical data at a frequency, and the trained model can be updated based on the updated historical data so that the prediction model is updated at the frequency. For example, the frequency can be about once every five minutes or higher.

At step S403, a characteristic of the target wafer that results from the first process can be predicted based on real-time data using the prediction model. In some embodiments, the predicted characteristic of the target wafer can be transferred from the prediction server to a buffer that queues requests from the prediction server and employs an available controller.

At step S404, an adjusted second process can be performed on the target wafer using a second processing tool that is instructed by a controller that receives the predicted characteristic of the target wafer from the prediction server and adjusts process inputs for the second processing tool. For example, the second processing tool can be a second etching tool, and the adjusted second process can be an adjusted second etching process.

It should be noted that additional steps can be provided before, during, and after the process 400, and some of the steps described can be replaced, eliminated, or performed in a different order for additional embodiments of the process 400. For example, prior to step S401, a plurality of historical wafers can be processed using the first processing tool, and the historical data can be collected on the plurality of historical wafers. Further, both manufacturing data and metrology data can be collected on the historical wafers.

The various embodiments described herein offer several advantages. For example, the models are updated frequently using historical data so that the prediction models can capture the latest status of the equipment and chamber and make reliable predictions. The buffer can coordinate between the prediction servers and the controllers and improve the efficiency of high volume manufacturing.

“Device” or “semiconductor device” as used herein generically refers to any suitable device, for example, memory circuits, a semiconductor chip (or die) with memory circuits formed on the semiconductor chip, a semiconductor wafer with multiple semiconductor dies formed on the semiconductor wafer, a stack of semiconductor chips, a semiconductor package that includes one or more semiconductor chips assembled on a package substrate, and the like.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

The substrate can be any suitable substrate, such as a silicon (Si) substrate, a germanium (Ge) substrate, a silicon-germanium (SiGe) substrate, and/or a silicon-on-insulator (SOI) substrate. The substrate may include a semiconductor material, for example, a Group IV semiconductor, a Group III-V compound semiconductor, or a Group II-VI oxide semiconductor. The Group IV semiconductor may include Si, Ge, or SiGe. The substrate may be a bulk wafer or an epitaxial layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An advanced process control (APC) system, comprising:
a first processing tool that performs a first process on a target wafer;
a second processing tool that performs a second process on the target wafer after the first process has been completed;
a prediction server including a prediction model for predicting a characteristic of the target wafer resulting from the first process using real-time data from the first process performed on the target wafer, parameters of the prediction model being updated by historical data of previous first processes; and
a controller that is coupled to the first and second processing tools, wherein after the first processing tool performs the first process on the target wafer, the controller instructs the second processing tool to perform an adjusted second process on the target wafer based on the characteristic of the target wafer predicted by the prediction model.

2. The APC system of claim 1, further comprising a model training server for updating a training model using the historical data so that parameters of the training model are synced to the prediction model.

3. The APC system of claim 2, wherein:
the historical data are updated by adding the real-time data to the historical data at a frequency, and
the trained model is updated based on the updated historical data so that the prediction model is updated at the frequency.

4. The APC system of claim 3, wherein the frequency is about once every five minutes or higher.

5. The APC system of claim 1, further comprising a buffer that queues requests from the prediction server and employs an available controller.

6. The APC system of claim 1, wherein:
the historical data includes manufacturing data of the previous first processes collected by the first processing tool, and
the real-time data includes manufacturing data from performing the first process on the target wafer collected by the first processing tool.

7. The APC system of claim 6, wherein the historical data further comprise metrology data of the previous first processes.

8. The APC system of claim 1, wherein the predicted characteristic of the target wafer resulting from the first process comprises at least one of critical dimension (CD) or etch rate (ER).

9. The APC system of claim 8, wherein:
the first process is an etching process, and
the first processing tool is an etching tool.

10. The APC system of claim 9, wherein:
the historical data includes at least one of CD or ER of the previous first processes and at least one of temperature, etchant, pressure, flow rate, or process time of the previous first processes, and
the real-time data includes at least one of temperature, etchant, pressure, flow rate, or process time of the first process performed on the target wafer.

11. The APC system of claim 8, wherein:
the second process is an etching process, and
the second tool is an etching tool.

12. The APC system of claim 11, wherein at least one of temperature, etchant, pressure, flow rate, or process time is adjusted by the controller to perform the adjusted second process.

13. An advanced process control (APC) system, comprising:
a first processing tool that performs a first process on a target wafer;
a second processing tool that performs a second process on the target wafer after the first process has been completed; and
a controller that is coupled to the first and second processing tools, wherein after the first processing tool performs the first process on the target wafer, the controller instructs the second processing tool to perform an adjusted second process on the target wafer based a characteristic of the target wafer resulting from the first process, the characteristic of the target wafer being predicted by a prediction model using real-time data from the first process performed on the target wafer, parameters of the prediction model being updated by historical data of previous first processes.

14. A method for implementing an APC system, the method comprising:
performing a first process on a target wafer using a first processing tool;
updating a prediction model in a prediction server based on historical data;
predicting a characteristic of the target wafer resulting from the first process based on real-time data using the prediction model; and
performing an adjusted second process on the target wafer using a second processing tool that is instructed by a controller that receives the predicted characteristic of the target wafer from the prediction server and adjusts process inputs for the second processing tool.

15. The method of claim 14, wherein updating the prediction model in the prediction server based on the historical data comprises:
updating a training model in a model training server using the historical data; and
syncing parameters of the training model to the prediction model.

16. The method of claim 15, further comprising:
updating the historical data by adding the real-time data to the historical data at a frequency; and
updating the trained model based on the updated historical data so that the prediction model is updated at the frequency.

17. The method of claim 16, wherein the frequency is about once every five minutes or higher.

18. The method of claim 14, wherein, after predicting the characteristic of the target wafer resulting from the first process based on the real-time data using the prediction model, the method further comprises:
transferring the predicted characteristic of the target wafer from the prediction server to a buffer that queues requests from the prediction server and employs an available controller.

19. The method of claim 14, further comprising:
processing a plurality of historical wafers using the first processing tool; and
collecting the historical data on the plurality of historical wafers.

20. The method of claim 19, wherein collecting the historical data on the plurality of historical wafers comprises:
collecting manufacturing data on the historical wafers from the first processing tool; and
collecting metrology data on the historical wafers from a metrology tool.
